(19) United States
(12) Patent Application Publication
(10) Pub. No.: US 2008/0012611 A1
(43) Pub. Date: Jan. 17, 2008

(54) Clock Generator Circuit With Spectrum Spreading

(76) Inventor: Yasuhito Sugimoto, Kyoto (JP)

Correspondence Address: CANTOR COLBURN, LLP, 55 GRIFFIN ROAD SOUTH, BLOOMFIELD, CT, 06002, US

(21) Appl. No.: 11/658,106

(22) PCT Filed: Jul. 20, 2005
(86) PCT No.: PCT/JP05/13280

§ 371 Date: Jan. 22, 2007

(30) Foreign Application Priority Data
Jul. 22, 2004 (JP) 2004-214856

(51) Int. Cl. H03B 19/00

(52) U.S. Cl. 327/117

(57) ABSTRACT

A clock generation circuit includes a PLL circuit 60 and a jitter inducing circuit. The jitter inducing circuit generates a bias current for driving the voltage-controlled oscillator of the PLL circuit and further induces fluctuation in the bias current. The jitter inducing circuit includes an oscillator and a current source. The fluctuation component generated by the oscillator is induced in the bias current. The oscillation frequency of the oscillator is a natural number multiple of the frequency of an input clock signal CKIN.

### BACKGROUND OF THE INVENTION

1. Field of the Invention

The present invention relates to a clock generation circuit and a communication apparatus using the same and, more particularly, to a technology for reducing unwanted radiation.

2. Description of the Related Art

Small information terminals such as a cellular phone and a personal digital assistant (PDA) use a clock generation circuit to drive a semiconductor device used inside the terminal or to generate a RF signal necessary for wireless communication. The clock generation circuit outputs a clock signal at a higher frequency as the operation speed of small information terminals is increased recently. Consequently, there is a problem in that electromagnetic wave radiated from the clock generation circuit causes malfunction of a peripheral circuit or another electronic device, or affects wireless communication.

Such a problem is known as electromagnetic interference (EMI). One of the methods to reduce EMI that has attracted interest is a technology for reducing unwanted radiation by spreading the spectrum of a clock signal obtained by the clock generation circuit by frequency modulation.

For example, patent document No. 1 discloses reducing unwanted radiation such that the spectrum of the output clock signal is spread by inducing fluctuation in the input clock signal fed to the phase lock loop (PLL) circuit or in the signal within the loop. Patent document No. 2 discloses reducing unwanted radiation by varying the oscillation frequency by varying a dividing factor of a frequency divider in the PLL circuit.

[Patent Document No. 1]

JP 2000-101424

[Patent Document No. 2]

JP 2001-7700

### SUMMARY OF THE INVENTION

The present invention achieves the same goal of reducing EMI as the technology described in the above-mentioned references such that unwanted radiation is reduced by spreading the spectrum of an output clock signal. However, the present invention differs from the related art in its method. A general purpose of the present invention is to provide a clock generation circuit in which unwanted radiation is reduced and the spread of desired spectrum is easily regulated.

The clock generation circuit according to one embodiment of the present invention is provided with a voltage-controlled oscillator and a jitter inducing circuit which induces fluctuation in a bias current for driving the voltage-controlled oscillator.

The oscillation frequency of the voltage-controlled oscillator varies in accordance with the value of the bias current for driving the voltage-controlled oscillator. Therefore, even if the oscillation control signal input to the voltage-controlled oscillator remains constant, fluctuation can be induced in the oscillation frequency of the voltage-controlled oscillator by inducing fluctuation in the bias current. This causes the oscillation frequency of the voltage-controlled oscillator to vary. Accordingly, the spectrum of the output clock signal of the clock generation circuit is spread so that unwanted radiation is reduced.

Another embodiment of the present invention also relates to a clock generation circuit. The clock generation circuit comprises: a phase comparator which detects a phase difference between an input clock signal and a frequency-divided version of an output clock signal and which outputs a phase difference indicator signal; a voltage-controlled oscillator which generates the output clock signal based upon the phase difference indicator signal; and a jitter inducing circuit which induces fluctuation in a bias current for driving the voltage-controlled oscillator.

According to this embodiment, fluctuation is induced by the jitter inducing circuit in a bias current of the voltage-controlled oscillator of the PLL circuit having a feedback loop, causing the oscillation frequency of the voltage-controlled oscillator to vary. Accordingly, the spectrum of the output clock signal of the clock generation circuit can be spread so that unwanted radiation is reduced.

The fluctuation induced in the bias current by the jitter inducing circuit may be an alternating signal. In this case, the spectrum of the output clock signal is smoothly spread on the basis of the alternating current. Therefore, unwanted radiation is suitably reduced.

The frequency of fluctuation induced in the bias current by the jitter inducing circuit may be a natural number multiple of the input clock signal. In the process of frequency division, the fluctuation component induced in the output clock signal is reduced to zero on an average over a period of the input clock signal. Only the jitter component inherent in the voltage-controlled oscillator is therefore fed back.

As a result, the spectrum can be spread while maintaining the central frequency at a fixed level because the fluctuation component does not affect the feedback loop.

The fluctuation induced in the bias current by the jitter inducing circuit may be controlled by an external signal.

Still another embodiment of the present invention also relates to a clock generation circuit. The clock generation circuit comprises: a phase comparator which detects a phase difference between an input clock signal and a frequency-divided version of an output clock signal and which outputs a phase difference indicator signal; a voltage-controlled oscillator which generates the output clock signal based upon the phase difference indicator signal; and a jitter inducing circuit which induces fluctuation in the phase difference indicator signal. The frequency of fluctuation induced in the phase difference indicator signal by the jitter inducing circuit may be a natural number multiple of the frequency of the input clock signal.

The phrase “induces fluctuation in the phase difference indicator signal” refers to induction of fluctuation in the phase difference indicator signal by the jitter inducing circuit somewhere on a path leading from the phase comparator to the voltage-controlled oscillator.

In the process of frequency division, the fluctuation component directly induced in the phase difference indicator signal is reduced to zero on an average over a period of the input clock signal. Only the jitter component inherent in the voltage-controlled oscillator is therefore fed back. As a result, the spectrum can be spread while leaving the loop unaffected and maintaining the central frequency at a fixed level.

Yet another embodiment of the present invention also relates to a clock generation circuit. The clock generation circuit comprises: a voltage-controlled oscillator; a jitter inducing circuit which induces fluctuation in a bias current for driving the voltage-controlled oscillator; and an input terminal for regulating the amount of fluctuation induced by the jitter inducing circuit.

Since the amount of fluctuation can be regulated externally according to this embodiment, the spectrum can be spread in a manner adapted to an apparatus in which the clock generation circuit is used so that unwanted radiation can be reduced.

The clock generation circuit may further comprise a control terminal for halting the operation of the jitter inducing circuit. If unwanted radiation does not present a problem, current consumption can be reduced by supplying an external signal to the control terminal so as to halt the operation of the jitter inducing circuit.

It is to be noted that any arbitrary combination or rearrangement of the above-described structural components and so forth are all effective as and encompassed by the present embodiments.

Moreover, this summary of the invention does not necessarily describe all necessary features so that the invention may also be sub-combination of these described features.

### Advantages of the Invention

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a block diagram showing the structure of a clock generation circuit according to a first embodiment of the present invention;

FIG. 2 is a circuit diagram showing an example of the structure of the voltage-controlled oscillator and the jitter inducing circuit;

FIGS. 3A-3C are graphs showing the time waveforms of voltage and current in the jitter inducing circuit;

FIG. 4 is a graph showing dependence of the oscillation control voltage Vosc and the oscillation frequency fosc of the voltage-controlled oscillator on a bias current;

FIGS. 5A-5E are graphs showing the time waveforms of current, voltage and frequency of the clock generation circuit;

FIG. 6 is a block diagram showing the structure of the clock generation circuit according to a second embodiment;

FIG. 7 is a block diagram showing the structure of a cellular phone in which the clock generation circuit of FIG. 1 or FIG. 6 is installed; and

FIG. 8 is a block diagram showing an alternative structure of a cellular phone in which the clock generation circuit of FIG. 1 or FIG. 6 is installed.

### DETAILED DESCRIPTION OF THE INVENTION

The invention will now be described based on preferred embodiments which do not intend to limit the scope of the present invention but exemplify the invention. All of the features and the combinations thereof described in the embodiment are not necessarily essential to the invention. The clock generation circuit described below is a PLL circuit which generates an output clock signal CKOUT based upon an input clock signal CKIN. The clock generation circuit is installed in a communication apparatus such as a cellular phone and is used to generate a high-frequency reference necessary for communication.

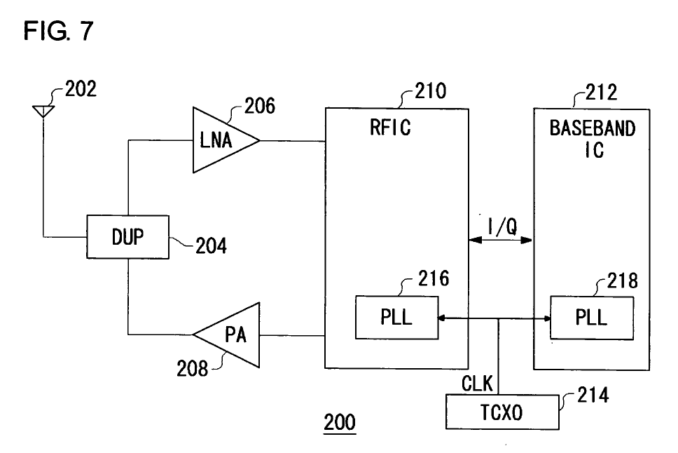

FIG. 7 is a block diagram showing the overall structure of a cellular phone 200 in which the clock generation circuit according to the embodiments is installed. The cellular phone 200 includes an antenna 202, a duplexer 204, a low-noise amplifier 206, a power amplifier 208, a RF (Radio-frequency) IC 210, a baseband IC 212 and a temperature-compensated crystal oscillator (hereinafter, referred to as TCXO) 214.

The TCXO 214 generates a reference clock signal CLK of the cellular phone 200 and outputs the same to the blocks of the cellular phone 200.

The baseband IC 212 is a chip for overall control of the cellular phone 200 and is used for signal processing such as data modulation and demodulation according to a communication scheme such as Wideband Code Division Multiple Access (WCDMA) and Global System for Mobile Communications (GSM). The baseband IC 212 includes an PLL 218. The PLL 218 receives the reference clock signal CLK output from the TCXO 214 so as to generate a periodic signal having a frequency obtained by multiplying the frequency of the reference clock signal CLK. The signal thus generated is used as an internal clock signal in the baseband IC 212.

The RFIC 210 includes an PLL 216 and a mixer (not shown). The PLL 216 receives the reference clock signal CLK output from the TCXO 214 so as to generate a signal having a frequency obtained by multiplying the frequency of the clock signal CLK. The mixer (not shown) performs mixing for frequency conversion (upconverting or downconverting), by using a local frequency signal generated by the PLL 216. The RFIC 210 performs I/Q modulation based upon an I/Q signal output from the baseband IC 212 and performs frequency conversion from a local frequency into a transmission frequency. The RFIC 210 outputs the resultant signal to the power amplifier 208. The power amplifier 208 amplifies the RF signal output from the RFIC 210 in accordance with a distance from a base station. The RF signal amplified by the RFIC 210 is input to the antenna 202 via the duplexer 204 and transmitted to the base station.

The duplexer 204 outputs a RF signal received by the antenna 202 to the low-noise amplifier 206. The low-noise amplifier 206 amplifies the received signal and outputs the amplified signal to the RFIC 210. The RFIC 210 converts the reception frequency of the output signal of the low noise amplifier 206 into the local frequency. The local frequency signal is subject to I/Q demodulation and output to the baseband IC 212.

Referring to FIG. 7, if the clock signal generated in the PLL 218 inside the baseband IC 212 is radiated as electromagnetic wave and is likely to affect the operation of the other parts of the circuitry, it is necessary to spread its spectrum so as to reduce EMI. On the other hand, spectrum spreading should preferably not be performed in the PLL 216 inside the RFIC 210 because doing so would affect modulation precision.

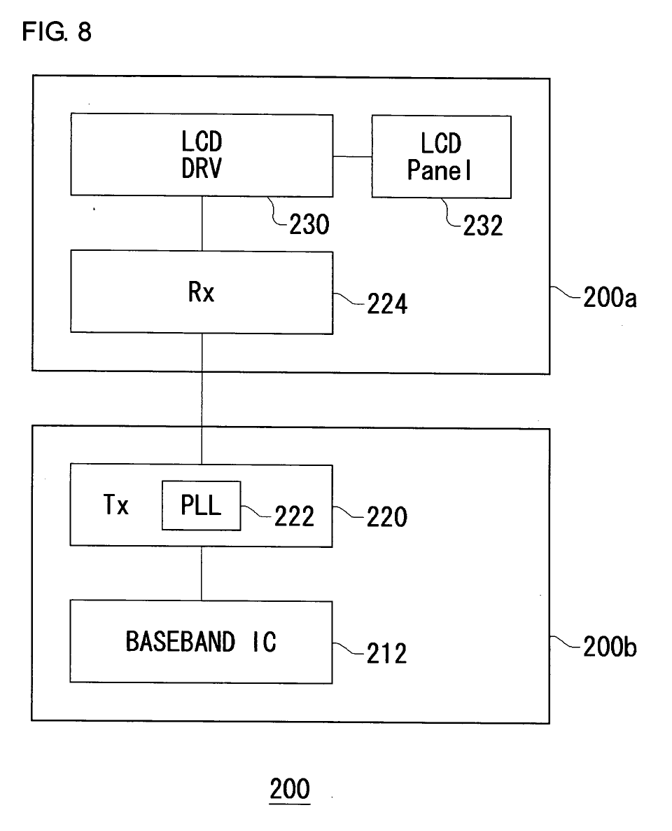

FIG. 8 is a block diagram showing the structure of a foldable cellular phone 200. The cellular phone 200 includes a first housing 200a in which a liquid crystal panel 232 is installed and a second housing 200b in which the baseband IC 212 is installed. The liquid crystal panel 232 and a liquid crystal panel driver 230 are installed in the first housing 200a.

The first housing 200a is provided with a receiver IC 224 and the second housing 200b is provided with a transceiver IC 220. Since the first housing 200a and the second housing 200b are connected to each other via a hinge, the number of data lines accommodated is restricted. The transceiver IC 220 and the receiver IC 224 are function ICs which perform parallel-to-serial conversion and transfer data between the first housing 200a and the second housing 200b using a relatively small number of lines. The first housing 200a and the second housing 200b may be connected to each other via a rotating mechanism.

The transceiver IC 220 receives a data signal and a clock signal output from the baseband IC 212. For example, the clock frequency of the signal output from the baseband IC 212 may be 13 MHz. The transceiver IC 220 is provided with a PLL 222 for multiplying the clock signal output from the baseband IC 212. The transceiver IC 220 uses the clock signal at 200 MHz generated by the PLL 222 to subject the data signal output from the baseband IC to parallel-to-serial conversion and transmits the serial signal to the receiver IC 224.

The receiver IC 224 subjects the data output from the transceiver IC 220 to serial-to-parallel conversion and outputs the parallel signal to the liquid crystal driver 230. The liquid crystal panel driver 230 displays the data on the liquid crystal panel 232.

In the cellular phone 200 of FIG. 8 with the above-mentioned structure, the clock signal at 200 MHz generated by the PLL 222 inside the transceiver 220 may cause unwanted radiation from the hinge. Thus, it is favorable to perform spectrum spreading in this case, too, in order to reduce EMI.

In the following embodiments, clock signal generation circuits suitably used in the PLL 218 inside the baseband IC 212 of the cellular phone 200 of FIG. 7 and in the PLL 222 inside the transceiver IC 220 of the cellular phone 200 of FIG. 8.

### FIRST EMBODIMENT

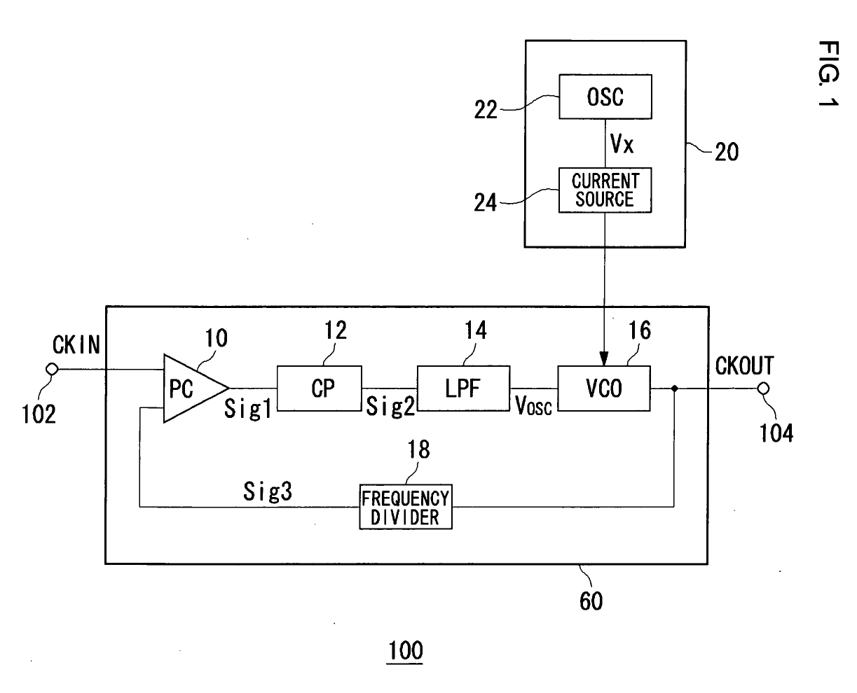

FIG. 1 shows the structure of the clock generation circuit 100 according to a first embodiment of the present invention.

The clock generation circuit 100 is provided with an input terminal 102 and an output terminal 104. Signals input to the input terminal and the output terminal will be referred to as an input clock signal CKIN and an output clock signal CKOUT, respectively. The frequency of the input clock signal CKIN will be referred to as the input clock frequency fIN and the frequency of the output clock signal CKOUT will be referred to as the output clock frequency fOUT.

The clock generation circuit 100 includes a PLL circuit 60 and a jitter inducing circuit 20.

The PLL circuit 60 includes a charge pump circuit 12, a low-pass filter 14, a voltage-controlled oscillator 16 and a frequency divider 18. The clock generation circuit 100 multiples the frequency of the input clock signal CKIN by a frequency dividing ratio of N configured in the frequency divider 18 and outputs the output clock signal CKOUT that results. Accordingly, the output clock frequency fOUT and the input clock frequency fIn are subject to feedback control such that the relation fOUT=n×fIN holds.

The phase comparator 30 receives the input clock signal CKIN and a feedback signal Sig3 obtained by frequency-dividing the output clock signal CKOUT. The phase comparator 10 outputs an UP phase difference indicator signal Sig1 or a DOWN phase difference indicator signal Sig1 in accordance with the phase difference between the signals compared. The phase difference indicator signal Sig1 is fed to the charge pump circuit 12.

The charge pump circuit 12 generates a charge pump signal Sig2 by charging and discharging a capacitor in accordance with the UP phase difference indicator signal Sig1 or the DOWN phase difference indicator signal Sig1. The charge pump circuit 12 outputs the charge pump signal Sig2 to the low-pass filter 14.

The low-pass filter 14 is a so-called loop filter. The low-pass filter 14 removes unwanted harmonics by smoothing the charge pump signal Sig2 and outputs the oscillation control signal Vosc with a predetermined loop time constant.

The oscillation control signal Vosc from which unwanted harmonics are removed by the low-pass filter 14 is input to the voltage-controlled oscillator 16. The voltage-controlled oscillator 16 oscillates at a frequency commensurate with the oscillation control voltage Vosc and outputs the output clock signal CLKOUT. The output clock signal CLKOUT is frequency-divided by the frequency divider 18 and input to the phase comparator 10 as the feedback signal Sig3. The frequency of the feedback signal Sig3 is given by fOUT/N, using the dividing ratio N of the frequency divider 18.

The PLL circuit 60 with the above structure controls the frequency of the feedback signal Sig3 given by fOUT/N to be equal to the input clock frequency fIN by feedback control. In other words, the frequency is controlled such that fOUT=fIN×N and locked accordingly.

The jitter inducing circuit 20 is a circuit which generates a bias current Ic of the voltage-controlled oscillator 16 so as to induce fluctuation. The jitter inducing circuit 20 includes a current source 24 and an oscillator 22. The jitter inducing circuit 20 has the function of varying the frequency of the output clock signal CKOUT by varying the bias current Ic of the voltage-controlled oscillator 16.

The oscillator 22 generates a sine-wave voltage Vx having a frequency which is a natural number (=n) multiple of the input clock signal CKIN. The sine-wave voltage Vx is given such that Vx=Ax×Sin (2π×n×fIN×t), using the input clock frequency fIN and the natural number n. For simplicity, it is assumed that n=1 in this embodiment. The amplitude Ax of the sine-wave voltage Vx generated by the oscillator 22 is determined in accordance with the spread of the spectrum required in the output clock signal CKOUT, as described later. The voltage generated by the oscillator 22 is input to the current source 24. The oscillator 22 is highly localized within the clock generation circuit 100 and the frequency thereof is low if the dividing ratio N of the frequency divider 18 is large. Therefore, the oscillator 22 does not present a problem of EMI. The influence from the oscillator 22 is further reduced by reducing the amplitude thereof.

The power source 24 generates the bias current Ic in accordance with the sine-wave voltage Vx output from the oscillator 22. Sinusoidal fluctuation is superimposed on the bias current Ic. The voltage-controlled oscillator 16 is driven based upon the bias current Ic.

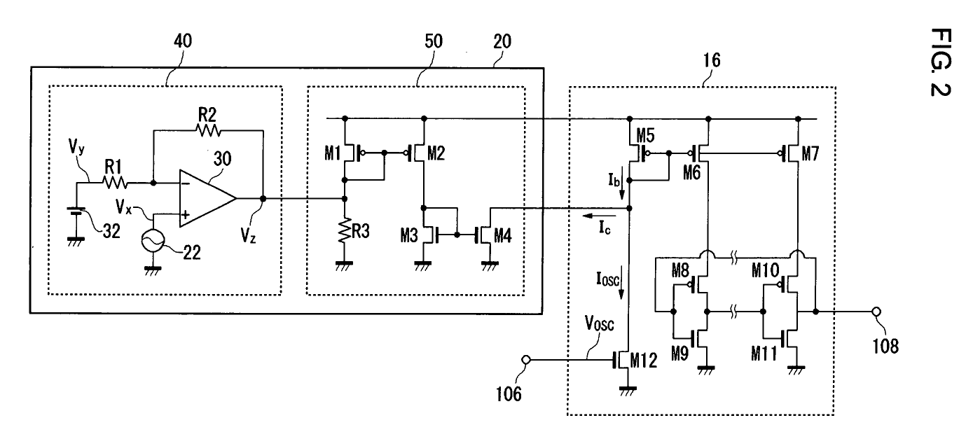

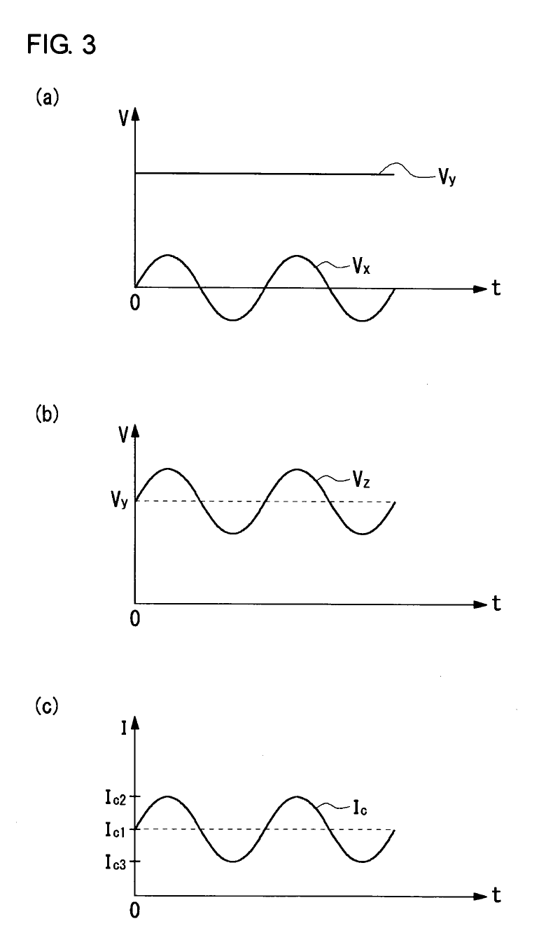

FIG. 2 shows an example of the structure of the voltage-controlled oscillator 16 and the jitter inducing circuit 20. FIGS. 3A-3C show the time waveforms of voltage and current in the jitter inducing circuit; In FIGS. 3A-3C, the vertical axis and the horizontal axis are simplified for ease of view and scaled for convenience's sake.

The jitter inducing circuit 20 includes a voltage source 40 and a voltage-to-current converting circuit 50. The voltage source 40 includes an error amplifier 30, resistors R1 and R2, and a constant voltage source 32. The oscillator 22 generates a sine wave voltage Vx. Given that the oscillator 32 outputs the voltage Vx and the constant voltage source 32 outputs a voltage Vy, the constant voltage source 40 outputs a voltage Vz centered at a constant level of (R1+R2)/R1×Vy and provided with sinusoidal fluctuation of an amplitude of R2/R1×Vx. FIGS. 3A and 3B show the time waveforms of voltages Vx, Vy and Vz.

The output voltage Vz of the voltage source 40 is input to the voltage-to-current converting circuit 50. A current given by Vz/R3 flows through a resistor R3 in the voltage-to-current converting circuit 50. A pair of transistors M1 and M2 form a current mirror, and a pair of transistors M3 and M4 also form a current mirror. Therefore, the bias current Ic flowing through the transistor M4 is proportional to the output voltage Vz of the voltage source 40. Thus, the jitter inducing circuit 20 generates the bias current Ic having sinusoidal fluctuation shown in FIG. 3C. The bias current Ic sinusoidally fluctuates around Ic1 in time and between the minimum level of Ic3 and the maximum level of Ic2.

The transistor M4 of the jitter inducing circuit 20 is connected to the gate and source of a transistor M5 of the voltage-controlled oscillator 16 and the gate of transistors M6-M7. The voltage-controlled oscillator 16 is driven by drawing the bias current Ic. The oscillation control signal Vosc is input to an input terminal 106 of the voltage-controlled oscillator 16 so that a current Iosc commensurate with the oscillation control signal Vosc flows through the transistor M12. Since a current Ib flowing through the transistor M5 is a sum of the bias current Ic generated by the jitter inducing circuit 20 and the current Iosc flowing through the transistor M12, Ib=Ic+Iosc.

The voltage-controlled oscillator 16 is formed by a ring oscillator which is commonly used. Transistors M8, M9, M10 and M11 form an inverter. A cascade connection of an odd number of inverters forms a ring oscillator. In the figure, inverters in the middle stages are omitted from the illustration for brevity.

The oscillation frequency of the ring oscillator is controlled by a current flowing through the transistors M6-M7. The transistors M6-M7 are connected to form a current mirror of the transistor M5. Therefore, a current dependent on the current Ib, which is a sum of the bias current Ic drawn by the jitter inducing circuit 20 and the current Iosc determined by the oscillation control voltage Vosc, flows through the transistors M6-M7. Therefore, the oscillation frequency of the ring oscillator can be controlled by the bias current Ic.

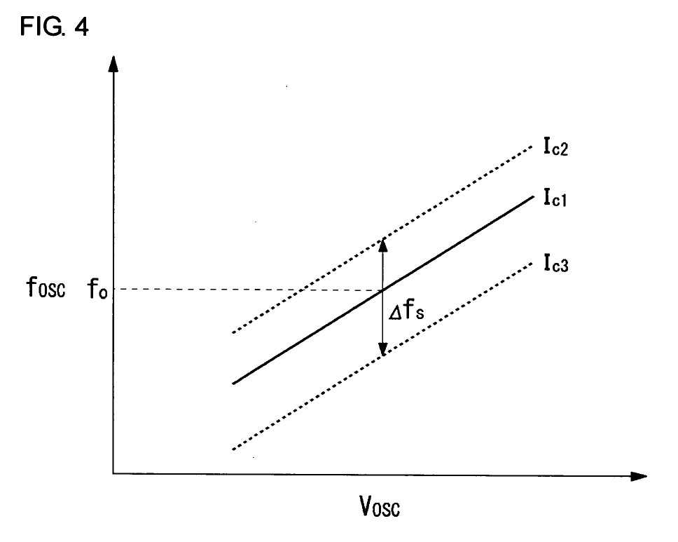

FIG. 4 is a graph showing a relation between the oscillation control voltage Vosc of the voltage-controlled oscillator 16 and the oscillation frequency fosc. The horizontal axis represents the oscillation control voltage Vosc and the vertical axis represents the oscillation frequency fosc. The bias current Ic is used as a parameter. The oscillation frequency fosc of the voltage-controlled oscillator 16 is varied by maintaining the bias current Ic at a fixed level and varying the oscillation control voltage Vosc.

By varying the bias current Ic, the oscillation control voltage vs. frequency characteristic is changed as indicated by broken lines of FIG. 4. As the bias current Ic is increased, the oscillation frequency fosc becomes high. Conversely, as the bias current Ic is decreased, the oscillation frequency fosc becomes low. Therefore, by varying the bias current Ic, the oscillation frequency fosc is varied under the constant oscillation frequency Vosc. By inducing sinusoidal fluctuation in the bias current Ic by the jitter inducing circuit 20, fluctuation is induced in the frequency of the output clock CKOUT of the voltage-controlled oscillator 16 so that the spectrum thereof is spread.

Given that the spread of the spectrum necessary to reduce unwanted radiation is Δfs, FIG. 4 gives an estimate on the amount of fluctuation that should be induced in the bias current Ic in order to obtain the spread Δfs. The amplitude of fluctuation in the bias current Ic is determined by the amplitude Ax of the oscillator 22 and the resistors R1 and R2. Therefore, a desired spread Δfs of the spectrum is obtained by regulating these values.

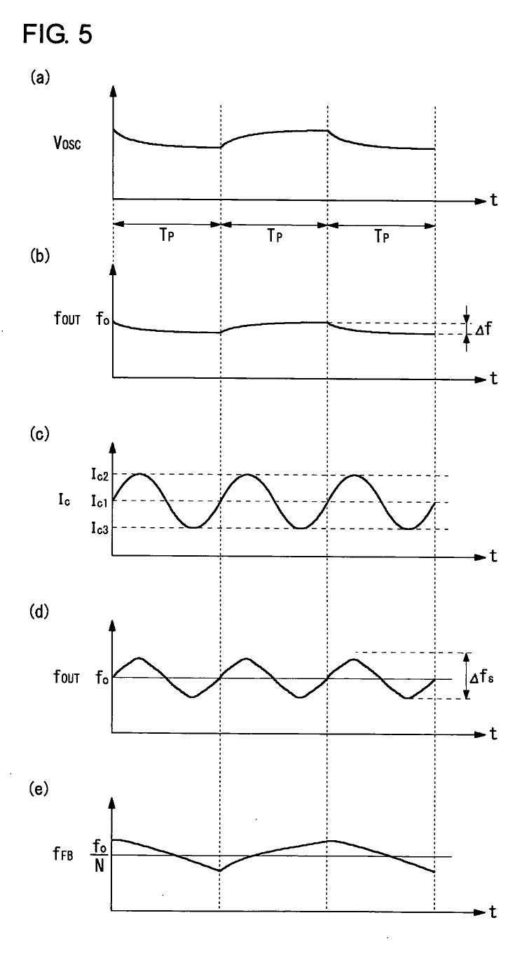

A description will now be given, with reference to FIGS. 5A-5E, of the operation of the clock generation circuit 100 with the structure described above. FIGS. 5A-5E show the time waveforms of current, voltage and frequency of the clock generation circuit 100. The notation “Tp” indicates a period of the input clock signal CKIN, which is a reciprocal of the input clock frequency fIN.

FIG. 5A shows the oscillation control voltage Vosc occurring when the jitter inducing circuit 20 is not used and the voltage-controlled oscillator 16 is driven by a constant current source in which the current level is fixed to Ic1. The frequency fOUT of the output clock signal CKOUT is determined in accordance with the relation shown in FIG. 4. Therefore, the time waveform shown in FIG. 5B is obtained when the oscillation control voltage Vosc shown in FIG. 5A is input. In this case, the output clock frequency fOUT is locked to the frequency fo and contains small jitter Δf that cannot be removed by the PLL circuit 60.

It will be assumed now that the current Ic as shown in FIG. 5C is generated by the jitter inducing circuit 20 and is used as a bias current to the voltage-oscillator controller 16. Fluctuation is induced in the bias current Ic by the sine wave at the same frequency as the input clock signal CKIN. The bias current Ic thus fluctuates around a central value of Ic1 and between the maximum level of Ic2 and the minimum level of Ic3.

As fluctuation shown in FIG. 5C is induced in the bias current Ic of the voltage-controlled oscillator 16, the relation shown in FIG. 4 demands that the frequency fOUT of the output clock signal CKOUT fluctuate around the frequency fc, as shown in FIG. 5D, resulting in the spread Δfs of the spectrum. Viewed from the temporal perspective, the fluctuation Δfs is a periodic signal which varies in level at a period of Tp.

The jitter component Δf shown in FIG. 5B is of a very small value since it represents frequency fluctuation occurring when the phase is locked by the PLL circuit 60. In contrast, Δfs shown in FIG. 5D is larger than Δf since it is generated by positively varying the bias current Ic of the voltage-controlled oscillator 16. For example, if the frequency fOUT of the output clock signal CKOUT is 100 MHz and fluctuation of 1% is induced, Δfs=1 MHz, whereas the jitter component Δf is on the order of 10-1000 kHz at most.

As shown in FIG. 5D, the frequency component Δfs of the fluctuation induced in the bias current Ic by the jitter inducing circuit 20 is canceled on an average over a period Tp. Accordingly, the average output clock frequency fOUT over a period Tp is approximately equal to the output clock frequency fo before the fluctuation shown in FIG. 5B is induced.

The output clock signal CKOUT is frequency-divided by a factor of N by the frequency divider 18. Since this is equivalent to the temporal integration or averaging of the output clock fOUT, the frequency component Δfs of the fluctuation is canceled. FIG. 5E is a graph showing the frequency fFB of the feedback signal Sig3 obtained by frequency division by the frequency divider 18. As illustrated, the fluctuation component induced in the output clock signal CKOUT by the jitter inducing circuit 20 is not observed.

As described above, the clock generation circuit 100 according to this embodiment is capable of spreading the spectrum of the output clock signal CKOUT around the frequency fo and with a spectrum spread of Δfs, without affecting the loop. Thereby, unwanted radiation is reduced.

The spectrum spread Δfs is determined by the amplitude of fluctuation induced in the bias current Ic by the jitter inducing circuit 20 and as such can be easily regulated to a desired value by controlling the amplitude A of the sine wave generated by the oscillator 22 or by controlling the resistors R1 and R2.

It is ensured that the frequency of fluctuation induced in the bias current Ic is a natural number multiple of the frequency fIN of the input clock signal CKIN, the fluctuation is canceled in the process of frequency division by the frequency divider 18 so that the influence of the jitter induced is reduced to near zero when phase comparison by the phase comparator 10 takes place. Thus, the jitter inducing circuit 20 may be excluded from consideration in a time-consuming loop simulation of the entire circuit which is performed in the circuit design stage. Estimation of the spectrum spread only requires considering the voltage-controlled oscillator 16 and the jitter inducing circuit 20 and so can be obtained without performing a loop simulation. Therefore, time required for design is reduced.

Further, by spreading the spectrum of the output clock signal, unwanted radiation from other circuits operated by using the output clock signal CKOUT is also reduced. Unwanted radiation from a channel of propagation of the output clock signal CKOUT is also reduced. Consequently, unwanted radiation from the system as a whole, including the clock generation circuit 100, is reduced.

### SECOND EMBODIMENT

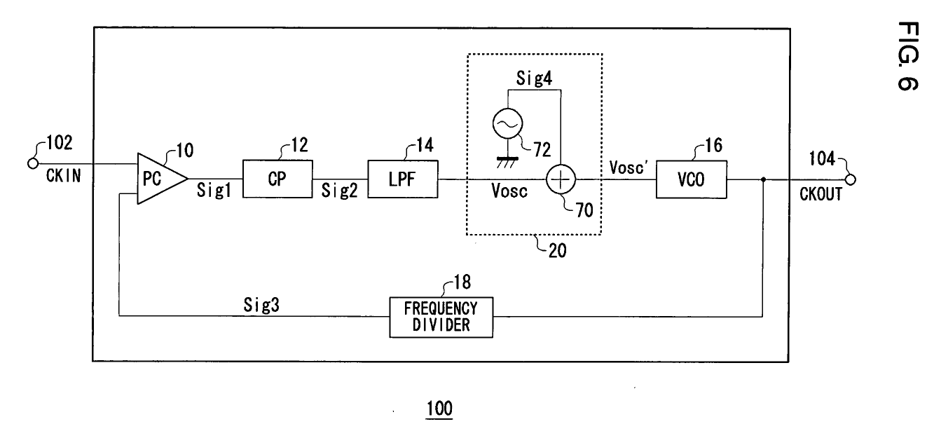

FIG. 6 is a block diagram showing the structure of the clock generation circuit 100 according to a second embodiment of the present invention. In FIG. 5, like numerals represent like elements and the description thereof is omitted as appropriate.

The clock generation circuit 100 according to the first embodiment spreads the spectrum by varying the bias current of the voltage-controlled oscillator 16. In contrast, the clock generation circuit 100 according to the second embodiment shown in FIG. 6 spreads the spectrum by inducing jitter in the oscillation control signal Vosc input to the voltage-controlled oscillator 16.

In the clock generation circuit 100 according to this embodiment, the jitter inducing circuit 20 is provided in a stage subsequent to the low-pass filter 14. The jitter inducing circuit 20 includes an adder 70 and an oscillator 72. The oscillator 72 outputs a jitter component Sig4 having a frequency which is a natural number multiple of the frequency of the input clock CKIN. The adder 70 adds the oscillation control signal Vosc output from the low-pass filter 14 and the jitter component Sig4 output from the oscillator 72. The oscillation control signal Vosc′ resulting from the addition is output to the voltage-controlled oscillator 16. The voltage-controlled oscillator 16 outputs the output clock signal CKOUT having a frequency defined by the oscillation control signal Vosc′ with the jitter component induced.

The jitter inducing circuit 20 may be provided in a stage preceding the low-pass filter 14.

In the clock generation circuit 100 according to this embodiment, fluctuation is induced in the oscillation control signal Vosc in a path leading from the phase comparator 10 to the voltage-controlled oscillator 16. The frequency of fluctuation component induced in the oscillation control signal Vosc is a natural number multiple of the frequency of the input clock signal CKIN. Therefore, in the process of frequency division, the fluctuation is reduced to zero on an average over a period. Therefore, only the jitter component inherent in the voltage-controlled oscillator is fed back. As a result, the spectrum can be spread while leaving the loop unaffected and maintaining the central frequency at a fixed level.

The embodiments described are only illustrative in nature and various variations in constituting elements and processes involved are possible. Those skilled in the art would readily appreciate that such variations are also within the scope of the present invention.

For example, the voltage source 40 and the voltage-to-current converter circuit 50 shown in FIG. 2 may be replaced by circuits having equivalent functions. What is essential is that the jitter inducing circuit 20 is capable of inducing fluctuation in the bias current Ic of the voltage-controlled oscillator 16.

The PLL circuit 60 may be designed not to use the charge pump circuit 12 of FIG. 1 or may be a PLL circuit which multiplies the input frequency fIN before outputting the same.

While it is assumed in the above embodiments that the frequency and amplitude of the fluctuation induced in the bias current Ic is fixed inside the jitter inducing circuit 20, variations are also possible. For example, the spectrum spread Δfs may have to be varied in the PLL circuit 60 used in a cellular phone in accordance with the modulation scheme or output power. In such a case, it is preferable that the spectrum spread Δfs be regulated by a circuit such as a baseband IC capable of integrated control of a set terminal. In this respect, a terminal may be provided for receiving a control signal for regulating the amount or frequency of fluctuation induced by the jitter inducing circuit 20 so that the frequency or amplitude of fluctuation is positively varied in accordance with the external control signal.

The operation of the jitter inducing circuit 20 may be halted externally when spectrum spreading is not necessary. For this purpose, a terminal for receiving a halt signal for halting the operation of the jitter inducing circuit may be provided. Current consumption can be reduced by halting the operation in accordance with the halt signal. In order to place the jitter inducing circuit 20 in the halted state, the oscillator 22, the error amplifier 30 or the constant current source 32 in the circuit diagram of FIG. 2 may be turned off, for example.

The range of fluctuation of the bias current Ic with an external signal may easily be regulated by controlling the amplitude Ax of the oscillator 22 or configuring the resistors R1 and R2 used in the jitter circuit 20 as variable resistors. Those skilled in the art would readily appreciate that other methods may be used to vary the current value of the current source by using an external signal.

While it is assumed that the oscillator 22 of the embodiments induces sinusoidal fluctuation in the above embodiments, other AC signals such as a triangular wave may be used in place of the sinusoidal signal. Also in this case, it is preferable that the frequency of the signal be a natural number multiple of the input clock frequency fIN such that the fluctuation component is reduced to zero on an average over a period Tp of the input clock signal CKIN.

Further, while the jitter inducing circuit 20 of the above embodiments used the oscillator 22 to induce fluctuation, the input signal may itself be used to generate an AC signal if the frequency of fluctuation is configured to be equal to the input clock frequency fIN. In this case, there is no need to provide the jitter inducing circuit 20 with an oscillator so that the structure of the circuit is simplified.

The fluctuation signal generated by the oscillator 22 may be externally input. The device in which the clock generation circuit 100 is installed may contain a block that uses a clock signal having a frequency which is natural number multiple of the input clock signal. The circuit is simplified by using such a clock signal.

The use of MOSFETs is described by way of example. However, other types of transistors such as bipolar transistors may be used. Selection may be in accordance with the design specification required of the clock circuit or the semiconductor fabrication process used.

The elements constituting the clock generation circuit 100 in the above embodiments may be integrally fabricated in their entirety or formed in separate integrated circuits. Alternatively, some of the elements may be formed as discrete components. Choice of elements to be integrated may be in accordance with the cost or occupied area.

While the preferred embodiments of the present invention have been described using specific terms, such description is for illustrative purposes only, and it is to be understood that changes and variations may be made without departing from the spirit or scope of the appended claims.

1. A clock generation circuit comprising:
a voltage-controlled oscillator; and
a jitter inducing circuit which induces jitter in a bias current for driving the voltage-controlled oscillator.

2. A clock generation circuit comprising:
a phase comparator which detects a phase difference between an input clock signal and a frequency-divided version of an output clock signal and which outputs a phase difference indicator signal;
a voltage-controlled oscillator which generates the output clock signal based upon the phase difference indicator signal; and
a jitter inducing circuit which induces fluctuation in a bias current for driving the voltage-controlled oscillator.

3. The clock generation circuit according to claim 1, wherein the fluctuation induced in the bias current by the jitter inducing circuit is an alternating signal.

4. The clock generation circuit according to claim 3, wherein the frequency of fluctuation induced in the bias current by the jitter inducing circuit is a natural number multiple of the frequency of the input clock signal.

5. The clock generation circuit according to claim 1, wherein fluctuation induced in the bias current by the jitter inducing circuit is controlled by an external signal.

6. A clock generation circuit comprising:
a phase comparator which detects a phase difference between an input clock signal and a frequency-divided version of an output clock signal and which outputs a phase difference indicator signal;
a voltage-controlled oscillator which generates the output clock signal based upon the phase difference indicator signal; and
a jitter inducing circuit which induces fluctuation in the phase difference indicator signal.

7. The clock generation circuit according to claim 6, wherein the frequency of fluctuation induced by the jitter inducing circuit is a natural number multiple of the frequency of the input clock signal.

8. A clock generation circuit comprising:
a voltage-controlled oscillator;
a jitter inducing circuit which induces fluctuation in a bias current for driving the voltage-controlled oscillator; and
an input terminal which receives a control signal for regulating the amount of fluctuation induced by the jitter inducing circuit.

9. The clock generation circuit according to claim 8, further comprising a control terminal receiving a halt signal for halting the operation of the jitter inducing circuit.

10. A communication apparatus provided with the clock generation circuit according to claim 1.

11. The clock generation circuit according to claim 2, wherein the fluctuation induced in the bias current by the jitter inducing circuit is an alternating signal.

12. The clock generation circuit according to claim 11, wherein the frequency of fluctuation induced in the bias current by the jitter inducing circuit is a natural number multiple of the frequency of the input clock signal.

13. The clock generation circuit according to claim 2, wherein fluctuation induced in the bias current by the jitter inducing circuit is controlled by an external signal.

14. A communications apparatus provided with the clock generation circuit according to claim 2.

15. A communication apparatus provided with the clock generation circuit according to claim 6.

16. A communication apparatus provided with the clock generation circuit according to claim 8.
